(19) United States
(12) Patent Application Publication
(10) Pub. No.: US 2023/0324816 A1
(43) Pub. Date: Oct. 12, 2023

(54) DEBRIS MITIGATION IN LASER PRODUCED PLASMAS USING THREE-DIMENSIONAL MAGNETIC NULLS

(71) Applicant: The Trustees of Princeton University, Princeton, NJ (US)

(72) Inventors: Ahmed Diallo, Plainsboro, NJ (US); Christopher Berg Smiet, Princeton, NJ (US); Ben Israeli, Princeton, NJ (US); Marien Simeni Simeni, Plainsboro, NJ (US)

(73) Assignee: The Trustees of Princeton University, Princeton, NJ (US)

(21) Appl. No.: 18/131,473

(22) Filed: Apr. 6, 2023

Related U.S. Application Data
(60) Provisional application No. 63/328,941, filed on Apr. 8, 2022.

(51) Int. Cl. G03F 7/00

(52) U.S. Cl. CPC G03F 7/70916; G03F 7/70033

(57) ABSTRACT

Disclosed is a method of debris mitigation in laser produced plasma EUV light sources. The method describes a class of magnetic field configurations which exhausts debris away from sensitive components of the EUV device. This class contains a large range of configurations that may be suited and tuned to specific application requirements with a high degree of flexibility and can be generated by coils that are located away from the light collection cone.

### CROSS-REFERENCE TO RELATED APPLICATIONS

The present application claims priority to U.S. Provisional Patent Application No. 63/328,941 Filed Apr. 8, 2022, the contents of which are incorporated by reference herein in its entirety.

### STATEMENT REGARDING FEDERALLY SPONSORED RESEARCH OR DEVELOPMENT

This invention was made with government support under Grant No. DE-AC02-09CH11466 awarded by the Department of Energy. The government has certain rights in the invention.

### TECHNICAL FIELD

The present application is drawn to extreme ultraviolet (EUV) lithography, and to techniques for mitigating debris generated during EUV lithography.

### BACKGROUND

Debris mitigation is one of the main challenges for furthering the development of reliable molten tin droplet-based extreme ultraviolet (EUV) lithography sources. Upon drive laser-tin droplet interaction, slow and fast tin ionic products as well as neutral atoms (within molten tin splashes) are generated. These constitute the so-called “debris”, which are responsible for damage to the delicate Mo/Si multilayer Bragg reflectors used for the collection of the produced EUV emission (at 13.5 nm±1%). Even though companies such as ASML managed to reduce collector mirror degradation rate (due to debris) down to 0.05% per gigapulse, further improvements are still required to extend the lifetime of EUV systems.

Recently, effective mitigation strategies for molten tin splashes and low energy (up to 4-5 keV) tin ions have been demonstrated. These mitigation strategies mainly consist in the introduction of up to a few millibar of H₂ background gas. H₂ serves two specific purposes: (1) It slows down low energy ions, reducing (through collisions) their kinetic energy before their impact on the mirror surfaces and (2) It cleans up the tin splashes (deposits) on the mirror surfaces through the chemical reaction: Sn (s)+4H (g)→SnH₄ (g). The end molecule SnH₄ (stannane), being gaseous, can be detached from the surfaces and pumped out of the vessel using widely available vacuum systems. It has to be noted here that H₂ mainly contributes to the generation of the H radicals responsible for the etching of Sn atoms on the mirror surfaces.

The use of a background gas also has significant downsides. Energetic H ions can implant in the mirror and aggregate between the Mo/Si layers causing blistering and delamination. Additionally, the aforementioned (stopping background gas shield) strategy cannot be extrapolated to the mitigation of fast (high energy>5 keV) ionic products since a significantly higher background gas pressure would be required for a substantial ion kinetic energy reduction. Obviously, a significant increase of the H₂ background pressure has detrimental effects on the EUV collection efficiency following EUV absorption by the background gas.

### BRIEF SUMMARY

In various aspects, a method for mitigating debris accumulation in a laser plasma EUV system may be provided. The method may include generating one or more three-dimensional magnetic nulls at one or more points, including those at which ions are created by an EUV system, such that substantially all ionized debris generated by the EUV system is channeled along magnetic field lines, substantially aligned with a fan plane or a spine line defined by magnetic fields that form the one or more three-dimensional magnetic nulls. The method may include forming the one or more three-dimensional magnetic nulls with magnetic fields generated by a plurality of electromagnetic coils (which may be, e.g., superconducting). In some embodiments, permanent magnets may be utilized in addition to or in place of the coils. The plurality of coils may be external to a light cone of the EUV system. The magnetic null that is generated may define a curved fan plane. The mitigation efficiency may be enhanced by introducing an additional smaller coil centered on a spine on a side of the magnetic null where the magnetic fields intersect sensitive components, such as collection optics. In various embodiments, the debris may be routed along a spine that intersects collection optics and the debris may be channeled through a hole in the collection optics. The method may include varying current through the plurality of coils to control the magnetic null structure and spatial location.

In various aspects, a laser plasma extreme ultraviolet (EUV) system may be provided. The system may include a collection mirror. The system may include a plurality of magnetic field generators (i.e., an electromagnetic coil or a permanent magnet) configured to generate a three-dimensional magnetic null at a first location. The three-dimensional magnetic null may define a spine and a fan plane. The first location may be being spatially separated from the collection mirror. The system may include a droplet source configured to position a droplet of a material at the first location. The system may include a laser source configured to generate a laser beam that passes through a hole in the collection mirror and interacts with the droplet at the first location to form ions.

The plurality of magnetic field generators may be, e.g., a plurality of electromagnetic coils, one or more of which may be superconducting. The plurality of magnetic field generators may be disposed external to a light cone formed during operation of the laser plasma EUV system. The plurality of magnetic field generators may be configured to create a magnetic null with a planar fan plane. The plurality of magnetic field generators may be configured to create a magnetic null with a non-planar fan plane.

The plurality of magnetic field generators may include two magnetic field generators having a first average diameter, and an additional magnetic field generator having a second average diameter, the second average diameter being smaller than the first average diameter. The additional magnetic field generator may be centered on a spine on the side of the magnetic null where the magnetic fields intersect sensitive components.

The system may include a power supply configured to vary current through the plurality of magnetic field generators to control a structure and/or spatial location of the magnetic null. The system may include at least one processor configured to control the power supply.

### BRIEF DESCRIPTION OF DRAWINGS

FIG. 1 is a simplified illustration of a system using a known perpendicular field mitigation technique.

FIG. 2 is a simplified illustration of a system using a magnetic null mitigation technique.

FIG. 3 is a simplified illustration of an arrangement of coils forming a non-planar fan plane.

FIG. 4 is a flowchart of a simplified method.

FIG. 5 is a simplified illustration of a system with a smaller coil enhancing debris mitigation.

FIG. 6 is a graph showing a trapping fraction (fraction of particles that have not reached a device wall) as a function of trajectory integration length. The perpendicular field has a trapping fraction of 60%, independent of trajectory length, reflecting the stable trapped trajectories in a mirror configuration. The trapping fraction in the null configuration decreases with integration time, reflecting the unstable nature of trajectories close to the null.

FIG. 7 is a graph showing the effect of integration length on apparent trapped fraction for parallel and null configurations.

FIG. 8A includes an illustration of the general EUV system geometry used for FIGS. 8B-8E.

FIG. 8B is a graph showing a distribution of ion strike points in the z direction for an EUV system with a null geometry calculated with a 10 m integration length.

FIG. 8C is a graph showing a distribution of ion strike points in the r direction for an EUV system with a null geometry calculated with a 10 m integration length.

FIG. 8D is a graph showing a distribution of ion strike points in the z direction for an EUV system with a perpendicular field calculated with a 10 m integration length.

FIG. 8E is a graph showing a distribution of ion strike points in the r direction for an EUV system with the perpendicular field calculated with a 10 m integration length.

### DETAILED DESCRIPTION

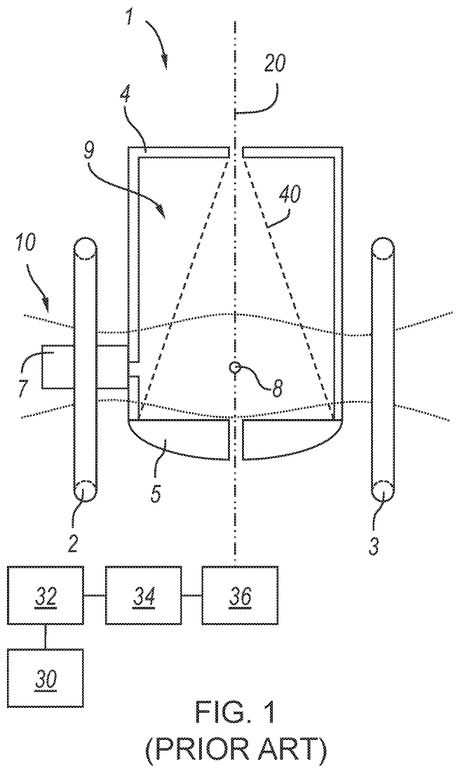

A known method that can complement the gas shield and prevent high-energy Sn ions from hitting the mirror is magnetic debris mitigation. Magnetic debris mitigation is based on the principle that charged particles are guided along magnetic field lines in a helical trajectory. In this way, the harmful Sn ions can be guided away from the mirror, and onto parts of the device that act as cold traps, removing them from the system. Referring to FIG. 1, one simple magnetic debris mitigation geometry 1 consists of two coils 2, 3 outside of the EUV system (e.g., cylindrical sidewalls 4 defining an internal volume of space that may include a background gas, the cylindrical sidewalls operably coupled to elliptical mirror 5), creating a magnetic field 10 perpendicular to the direction of light emission 20 or “light beam” (e.g., indirectly from one or more EUV light sources 30, such as an EUV laser, via one or more optical components, such as filters 32, mirrors 34, lenses 36, etc.). This geometry has been well-described previously. This configuration can be called the perpendicular field. One or more droplets 8 of a predetermined material (e.g., Sn droplets) may be passed into an internal volume of space 9 defined by the cylindrical sidewalls using, e.g., a droplet source 7 configured to position the droplet at a particular location.

A non-constant field can trap ions because of the magnetic mirroring effect, caused by the adiabatic invariance of the magnetic moment of a particle in a magnetic field. A charged particle moving along a helical path parallel to a magnetic field into a region of stronger magnetic field decreases its gyroradius, and must increase its perpendicular velocity ν to conserve magnetic moment. The parallel velocity ν decreases, and in a sufficiently strong field the particle is reflected back. This mechanism is used for confinement in nuclear fusion devices called magnetic mirrors.

Though the goal of debris mitigation and magnetic confinement are opposite, the governing equations are identical. Magnetic mirrors will always lose a fraction of the particles confined, which can be expressed in terms of the mirror ratio rₘᵢᵣᵣₒᵣ=Bₘₐₓ/Bₘᵢₙ. Particles where v_{∥}/v_{⊥}>\sqrt{rₘᵢᵣᵣₒᵣ−1}are in a “loss cone” and will escape the mirror; all other particles are trapped in the mirror.

In an EUV debris mitigation system the ratio of Bₘₐₓ/Bₘᵢₙ can be varied. A Helmholtz configuration would have minimal trapping, but requires very large coils, stored magnetic energy, and therefore cost of the system. Smaller coils will create a field sufficient for deflecting the heavy ions away from the mirror.

Trapped ions however are a problem for the EUV system. The process of pitch angle scattering can scatter ions into the loss cone and remove them, but there is always a finite probability for charge exchange. This will lower the ionization state of the Sn ion, causing a deterioration of confinement, and eventual neutralization. The neutralized ion cannot be confined by the field and flies in a straight trajectory, with a high probability of hitting the mirror, unless the density of buffer gas is high enough to stop it. The perpendicular field therefore still requires a significant buffer gas pressure.

A radically different buffer gas composition optimum can be found if the gas does not need to stop the ions. In the mirror configuration, ions are trapped because of adiabatic invariance, but this invariance is lost when the particle reaches a point of very low magnetic field.

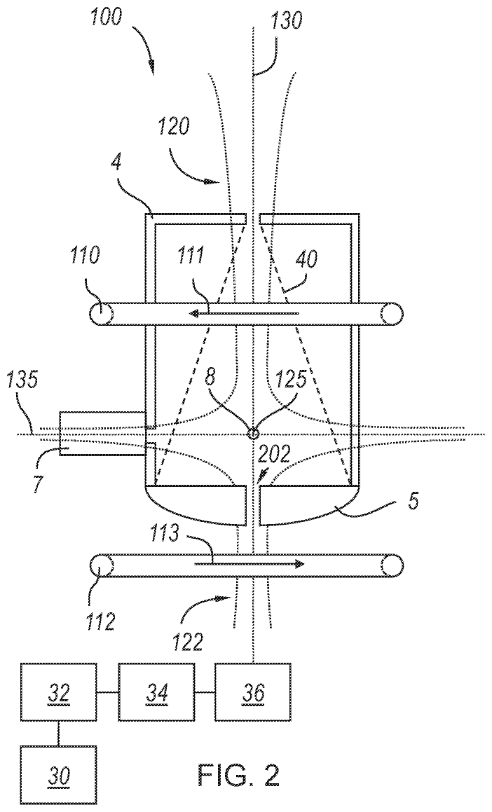

The systems and techniques disclosed herein therefore consider a magnetic configuration that does not exhibit trapping for the purposes of debris mitigation, specifically a configuration containing a magnetic null. A magnetic neutral point (or null) is a location where the magnetic field is topologically required to vanish. Such a configuration can be created with two spatially separated coils that generate opposing magnetic fields. Referring to FIG. 2, a system 100 may include two spatially separated coils 110, 112 (which may be, e.g., coaxially aligned) generating opposing magnetic fields 120, 122. A magnetic neutral point 125 has a universal magnetic structure: a spine line 130 where field lines asymptotically converge (in the two-coil case with current flowing in opposing directions (e.g., directions 111, 113), this is along the center of the two coils), and a fan plane 135, along which the field lines spread out.

As will be understood, while electromagnetic coils are shown in FIG. 2, other components capable of generating similar magnetic fields may be used. For example, one or more coils may be replaced with one or more permanent magnets, provided the permanent magnets are configured to generate the magnetic fields as disclosed herein. Similarly, one or more coils may be superconducting coils.

Ion trajectories around a null lie on erratic trajectories, as each time they pass by the null they pick up a new random pitch angle (v_{∥}/v_{⊥}).

As shown in FIG. 2, a null configuration can be created with just two coils creating magnetic fields in opposing directions, which cancel each other in the center to create the null. If the null is placed where the tin ions are generated (see, e.g., Sn droplet 8), their trajectories will be erratic, and they will eventually leave the system. Specifically, the ionized debris will generally leave in a direction substantially parallel to the fan plane 135, or substantially parallel to the spine line, and will generally avoid hitting the mirror.

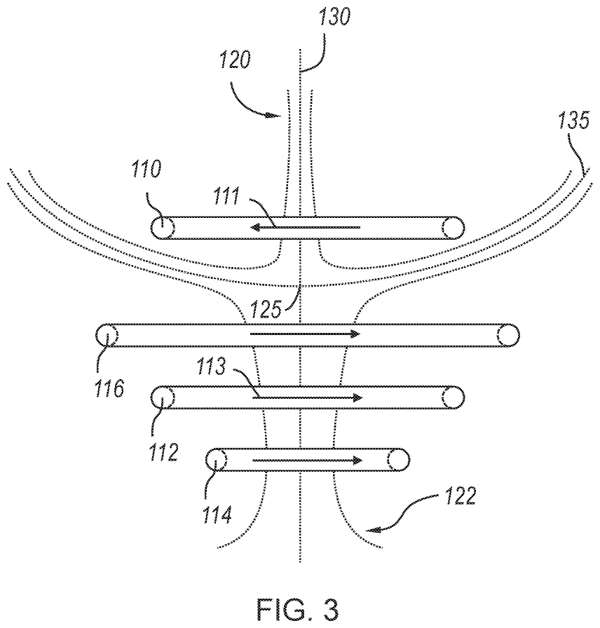

While in some cases, the fan plane may be a flat plane, other arrangements can exist. For example, referring to FIG. 3, if the coils are arranged such that the opposing fields 120, 122 generated by the coils are not symmetrical, the fan plane may have a non-planar shape. For example, if the system is configured to have a first group of coils having current flowing in a first direction (e.g., direction 113) and a second group of coils having current flowing in an opposite direction (e.g., direction 111), and there are more coils (e.g., three “bottom” coils 112, 114, 116) having current flowing in the first direction than the second (e.g., only the single “top” coil 110 is shown having current flowing in opposite direction), and especially an average diameter of one coil of the first group is a different diameter than coils in the second group (here, coils 114 has a smaller average diameter and coil 116 has a larger average diameter as compared to coil 110), a curved fan plane may be generated.

The coils are preferably disposed external to a light cone 40 of the EUV system.

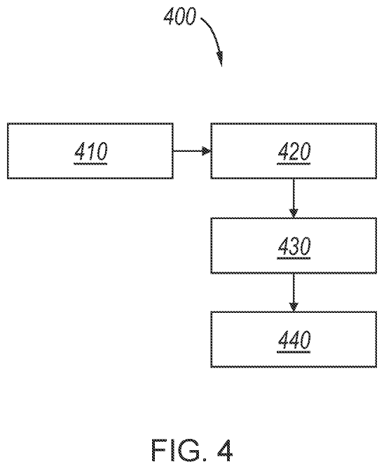

Thus, as seen in FIG. 4, in some embodiments, a method for mitigating debris accumulation in a laser plasma extreme ultraviolet (EUV) system may be provided.

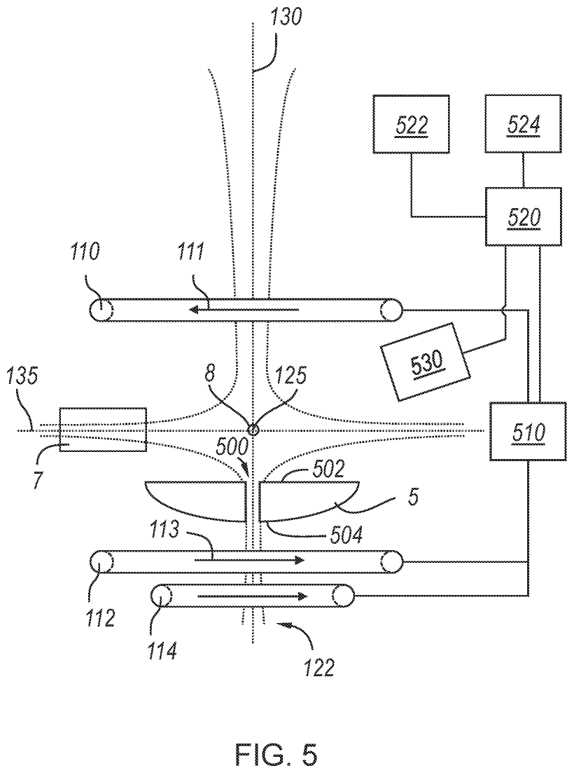

In some embodiments, the method 400 may include providing 410 a system as disclosed herein. Various enhancements to improve mitigation efficiency may be introduced. For example, this step may include introducing an additional smaller coil (e.g., a coil having an average diameter smaller than an average diameter of at least one other coil) centered on a spine on a side (of the null point) where the spine would intersect sensitive components (such as a mirror). As seen in FIG. 5, smaller coil 114 is on the same side of the null point 125 as the mirror 5, causing the magnetic field 122 on that side to have a smaller footprint (e.g., cross-sectional area) at the mirror as opposed to when the smaller coil is not in place.

The method may include generating 420 one or more three-dimensional magnetic nulls at one or more points, including those points at which ions are created by an EUV system, such that substantially all ionized debris generated by the EUV system is channeled along magnetic field lines, substantially aligned with a fan plane or a spine line defined the magnetic fields that form the one or more three-dimensional magnetic nulls. In some embodiments, nulls are only located where an ion may be generated. In some embodiments, one or more nulls are located in a position where an ion is not generated.

The magnetic fields forming the one or more three-dimensional magnetic nulls may be generated by one or more magnetic field generators, including one or more coils, one or more permanent magnets, or a combination thereof. For example, in some embodiments, the magnetic fields may be generated by a plurality of coils. As disclosed herein, the magnetic field generators may be disposed external to a light cone of the EUV system. As disclosed herein, a magnetic null with a planar fan plane or a non-planar fan plane (e.g., a curved plane) may be created.

In some embodiments, the method may include routing 430 debris along a spine may intersect collection optics, where the debris is channeled through a hole in the collection optics. Referring to FIG. 5, collection optics (such as, e.g., collector mirror 5) may include a hole 500 extending from a first surface 502 of the collection optics to a second surface 504 of the collection optics opposite the first surface.

In some embodiments, the method may include varying 440 current through the plurality of coils to control the magnetic null structure and spatial location. Referring to FIG. 5, a power supply operably coupled to the coils may provide varying current to one or more of the coils to control the magnetic fields, thereby adjusting the structure and location of the magnetic null. In some embodiments, one or more processors 520 (which may be coupled to a memory 522 and/or a non-transitory computer readable storage medium 524).

The one or more processor(s) may be coupled to one or more sensors or detector(s) 530. For example, a detector may be used to detect where the location where the droplets are being ionized, and based on the determined location, the processor(s) may determine how to adjust the current to ensure the magnetic null is aligned with that location.

It will be noted that this debris mitigation can accomplished by controlling the magnetic fields generated by the coils; that is, no shielding units (such as a ferromagnetic guide magnetized in an opposite direction to the magnetic field generated by the coils) are necessary. In some embodiments, the system may be free of such shielding units.

One of skill in the art will recognize improvements over previous approaches. For example, U.S. Pat. No. 6,987,279 discloses magnetic field generating means for generating a magnetic field within a collection optical system that traps charged particles radiating from a plasma, where ions are reflected from regions of high field strength. Here, however, the system does not trap particles. Indeed, the magnetic null cannot be described as ‘trapping’ the energies of interest, as the magnetic field is zero where the ions are created, but the global structure provides a guiding (not trapping) effect, channeling the ions in the proper direction along the fan. This can be understood as occurring because the geometry of the null allows much lower field strength along the fan plane, so that the guiding effect dominates.

Similarly, U.S. Pat. No. 8,586,953 discloses a magnetic field forming unit including (1) plural coils configured to form, when applied with electric currents, magnetic fields having different intensity from each other at both sides of a position where the target material is irradiated with the laser beam and (2) a shielding unit configured to shield a part of the magnetic fields formed by said plural coils. However, the system does not create a null with multiple coils, the field strength is not different at both sides from a position where a target material (e.g., a Sn droplet) is irradiated.

Finally, U.S. Pat. No. 8,354,657 discloses a magnetic field forming means for forming an asymmetric magnetic field at the location of plasma generation with a coil in a laser EUV device. “Asymmetric” as used in that disclosure refers to a lack of symmetry in a specific direction. In the present application, at the location of plasma generation the magnetic field is not asymmetric. It is zero, but the magnitude varies symmetrically around the neutral point. The null configuration is point-wise symmetric in magnitude (two locations opposite the null have exactly the same magnitude), and point-wise antisymmetric in magnetic field direction (two locations opposite the null have exactly opposite field direction. Mathematically, antisymmetry is a form of symmetry, and thus generating the null does not utilize asymmetry.

Thus, the present disclosure provides improvements based on the unique properties of using a null for debris mitigation, for at least the following reasons. First, the disclosed approach does not trap any particles in the relevant energy range; all ions are translated along the null to the wall. On a theoretical basis, even much lower energy ions will eventually escape, as they acquire a different pitch angle each time they pass the null, and will eventually enter the fan with a pitch angle within the loss cone. Second, this approach uses the topological structure of a magnetic null, i.e. the fan and the spine structure. Third, this topology is not captured in any of the configurations above, and is a mathematically precisely defined, indisputably different geometry than that of a magnetic field which does not contain a null. Fourth, this mitigation method steers the ion in a predictable direction. Fifth, although this is a magnetic mitigation method, the magnetic field strength at the location of the plasma is actually zero, and as such, It does not modify the laser plasma interaction.

### EXAMPLES

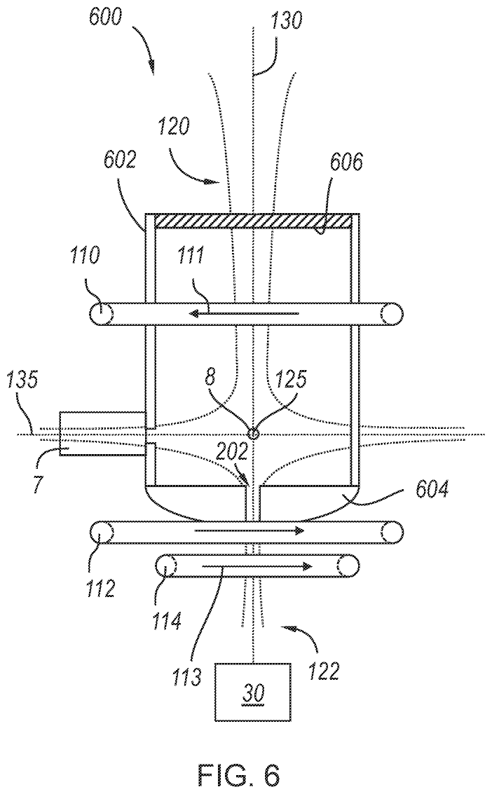

A model EUV system geometry is based on the publicly available parameters of the EUV system utilized by ASML in their next-generation photolithography machines. Referring to FIG. 6, the simulated geometry 600 consists of a cylindrical wall 602, capped with an elliptical mirror 604 at one end and a flat plate 606 at the other end. Magnetic field lines 120, 122 are shown. The cylinder is 30 cm in radius and has its axis passing through the origin (here, null point 125). The mirror is elliptical with one focus at the origin, the center of the mirror located 20 cm from this focus, an inter-focal distance of 60 cm, and the axis coinciding with that of the cylinder. The mirror has a 6 cm diameter circular hole 202 at its center for the excitation laser (e.g., from light source 30) to pass through. The plate 606 is located opposite to the mirror, 60 cm from the origin, normal to the device axis. With this choice of parameters, the mirror intersects the cylindrical wall at z=−3.07 cm. This example will work in cylindrical coordinates, with the z-axis coinciding with the device axis and the mirror located at negative z. Ions originate at the origin, the focus of the elliptic mirror.

The magnetic field is generated by three circular coils 110, 112, 114, all positioned coaxial to the cylinder. The magnetic field of the coils is calculated using the Biot-Savart Law, and the coils are approximated as filamentary, consisting of 1000 piecewise linear segments. The two primary coils 110, 112 have a radius of 35 cm. Their axial locations and currents are taken to be variable. The coil closer to the mirror may be referred to as coil 1 and the coil further from the mirror may be referred to as coil 2. A tertiary coil 114 of 8 cm radius is placed below the mirror, at z=−22 cm. Its field is fixed at 0.5 T, pointed toward positive z. This coil may be referred to as coil 3. These three coils create a magnetic null geometry, as is seen from the field lines in FIG. 6. Coils 1 and 2 create the majority of the field, and coil 3 pinches the magnetic field lines closer together at the mirror. This additional coil concentrates the strike points of the ions, guiding them into the hole in the mirror, and additionally increases the field strength, reflecting more ions away from the mirror.

The variable parameters defining the magnetic field geometry are the axial locations and currents/fields of the two primary coils. One can vary the axial locations of both coils and the field of coil 1. The field of coil 2 (B₂) will be constrained to place a magnetic null at the origin. The location of coil 1 is varied from z₁=−22 cm to z₁=0 cm in 5 steps, and the position of coil 2 is varied between z₂=0 cm and z₂=50 cm in 5 steps. The field of coil 1 is varied between B₁=0 and B₁=2 T (pointing toward positive z) in 10 steps. If the field magnitude of coil 2 required to produce a null at the origin exceeds 2 T, the configuration is discarded. Of the 250 possible location and field combinations, 113 had an acceptable coil 2 field strength and were used.

A perpendicular field configuration was also tested, consisting of two coils, creating a magnetic field perpendicular to the z-axis. The same wall and mirror geometry and the same ion populations as in the magnetic null simulations are used. The coils in this test configuration are of radius 33 cm and are 35 cm from the origin on either side of the device. Field lines of this configuration are shown in FIG. 1. The magnetic field strength is lower in the center, as is seen from the bulging of the field lines. This can cause trapping of ions, which can be reflected from the higher field regions near the coils.

### Ion Distribution

Discrete tin ion populations with fixed energy and charge state were considered. The populations have energies between 1 eV and 10 keV, divided logarithmically in 10 steps, and with all integer charge states between +1 and +8. For each coil configuration, the trajectories of 256 ions from each population were integrated, totalling 20,480 trajectories per configuration.

In order to consider a distribution of ion energies and charges that might realistically reflect the ion flux in a real device, ion counts were normalized with respect to a distribution during analysis. Since these measurements do not encompass the whole energy considered at all charge states, the ion count was assumed to be zero outside the measured ranges. The ion trajectories were integrated by numerically solving the Lorentz equation as two coupled first-order differential equations for the particle velocity v and position x:

$$\frac{\partial v}{\partial t} = \frac{{q}_{i o n}}{{m}_{i o n}} ( v \times B ( x ) ) \qquad ( 1 )$$

$$\frac{\partial x}{\partial t} = v \qquad ( 2 )$$

where qᵢₒₙ is the charge of the ion, mᵢₒₙ is the mass of a tin ion and B is the magnetic field vector, calculated using the Biot-Savart Law. The electric term in the Lorentz equation is ignored, as the electric field is assumed negligible on the whole device scale. The integration was performed using the DOP853 integration routine implementing an 8th order Runge-Kutta method, and the equations were solved in Python using just-in-time compilation with Numba for evaluation of the Biot-Savart integral. The initial condition for the position x is the origin, and the velocity magnitude |ν| is specified by the ion energy through ν=2 E/mᵢₒₙ. The direction of the velocity is randomly chosen from a uniform spherical distribution. Each trajectory is integrated until either it intersects the wall or mirror, or it reaches a fixed length, set to 5 meters in the case of the parameter scan.

An inverse relation between trapping and mitigation can be seen, with a reduction in ion flux to the mirror corresponding to an apparent increase in the number of ions trapped in the null for longer than the integration length. As might be expected, stronger fields are seen to produce greater mitigation, but also greater trapping (due to mirroring effects). The perpendicular field can produce a comparable or smaller ion flux to the mirror, again correlating with field strength, but with substantially higher trapping. As discussed above, the trapping rate of the perpendicular field is determined by coil geometry and is independent of field strength.

In order to further investigate the comparative performance of these two magnetic field topologies, the null configuration from the parameter scan which had the lowest ion flux to the mirror for further study was selected, comparing it against the perpendicular field configuration with a similar (2.0 T) field strength. The null configuration had coil 1 located at z=−22 cm and coil 2 at z=25 cm. These configurations, and their performance are detailed in table 1, below.

TABLE 1
Parameters for the compared null and perpendicular field configurations.
A configuration with no magnetic field is included as a baseline.
Ion fractions are indicated for an integration length of 10 m.

| | Null | Perp. field | No field |
|---|---|---|---|
| Coil fields (T) | 1.56 (coil 1) | 2.0 | N/A |
| | 1.83 (coil 2) | 2.0 | |
| | 0.50 (coil 3) | | |
| Ion fraction hitting mirror (%) | 0.0039 | 0.00040 | 42 |
| Ion fraction trapped (%) | 2.1 | 62 | 0.0 |

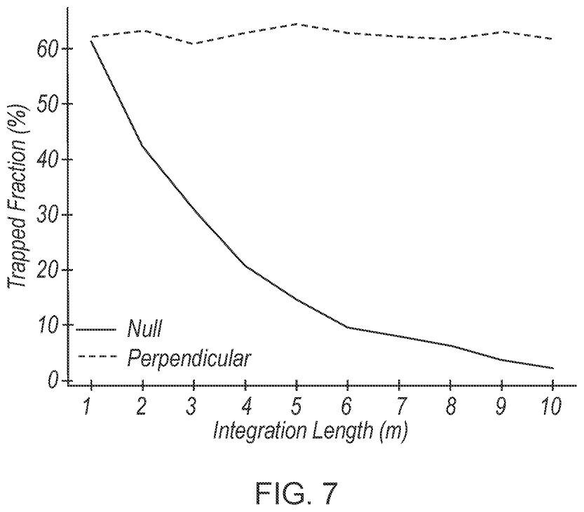

As a means to quantify the trapping behavior of these two configurations, the simulation was repeated with varied integration length in order to observe the effect on apparent trapped fraction. The results are shown in FIG. 7. The trapped fraction of the perpendicular field remains stable, indicating that these ions are the population trapped within the magnetic mirror. The apparently trapped fraction in the null configuration, however, decreases monotonically with integration length. This is due to the erratic trajectories of the ions, which acquire a new pitch angle with each pass of the null, allowing them to eventually escape.

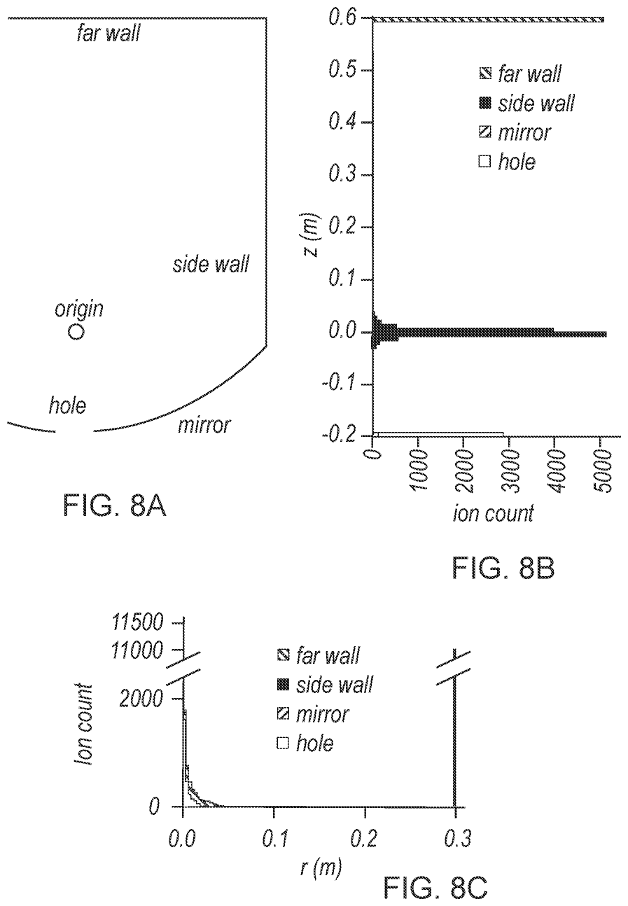

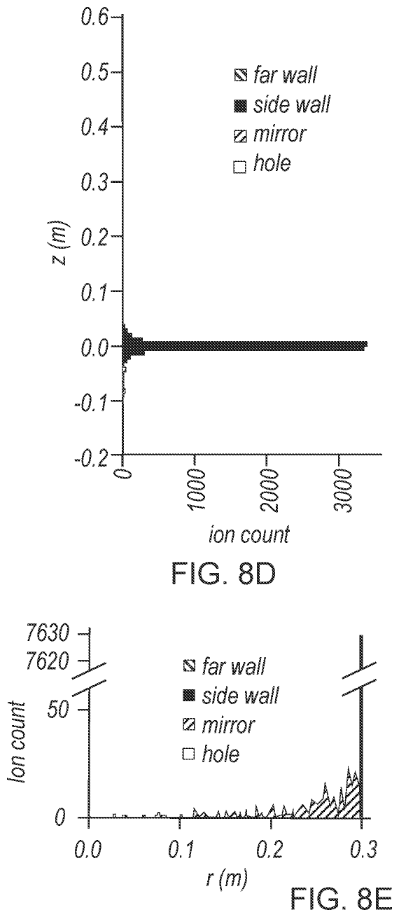

The distribution of ion deposition on the mirror and vessel wall for a generalized system (see FIG. 8A) for use with either the null configuration or a parallel field configuration. The ion strike distibutions can be seen in FIGS. 8B-8C and 8D-8E, respectively. As seen, the null configuration directs ions along its fan plane, forming a ring around the side wall of the vessel, and along its spine, into the hole in the mirror or toward the center of the far wall of the vessel. The perpendicular field directs the ions towards two regions on opposite sides of the vessel side wall, but the mirror is within those regions.

This example demonstrates that a magnetic null geometry is able to prevent the vast majority of tin ions from hitting the mirror in a realistically-dimensioned EUV system, without any trapping. The disclosed approach can yield very similar mitigation effectiveness results compared to a parallel field configuration (e.g., 1 ion in 10⁵ hitting the collector mirror). However, magnetic nulls offer the unique additional capability of controlling the fraction of ions trapped within the system. Furthermore, a non-trapping configuration can be obtained.

This non-trapping configuration has several potential benefits over the perpendicular field configuration, including that it can allow for different composition, it reduces the ionization of the background gas induced by the fast ionic debris, and it spreads the ion strikepoint distribution over a ring in the device.

The perpendicular field requires a background gas to stop the trapped ions when they eventually neutralize, as they will then be unconfined. With the null configuration, the calculus changes completely because all ions are on unstable orbits that eventually leave the system safely. A minimal gas pressure with a long mean-free-path between ion exchange events becomes feasible, and could help alleviate some of the issues caused by traditional use of a buffer gas: blistering due to ion implantation and significant EUV absorption by the gas. That said, the optimum operational regime will likely still include minimal buffer gas that includes hydrogen, e.g., to clean the mirror via the formation of gaseous stannane.

As disclosed herein, the magnetic null prevents a fraction of ions from hitting the mirror comparable to that of the perpendicular field, but does not trap any ions due to the loss of adiabatic invariance when the trajectories pass close to the null. This technology can potentially improve LPP-based EUV photolithography system efficiency and lifetime, and allows for a different, more efficient formulation of buffer gas.

What is claimed is:

1. A method for mitigating debris accumulation in a laser plasma extreme ultraviolet (EUV) system, comprising:
generating one or more three-dimensional magnetic nulls at one or more points at which an ion is created by an EUV system, such that substantially all ionized debris generated by the EUV system is channeled along magnetic field lines, substantially aligned with a fan plane or a spine line defined by magnetic fields that form the one or more three-dimensional magnetic nulls.

2. The method of claim 1, wherein magnetic fields forming the one or more three-dimensional magnetic nulls are generated by a plurality of electromagnetic coils and/or permanent magnets.

3. The method of claim 2, wherein the plurality of electromagnetic coils and/or permanent magnets is external to a light cone of the EUV system.

4. The method of claim 2, wherein a magnetic null with a curved fan plane is created.

5. The method of claim 2, wherein mitigation efficiency is enhanced by introducing an additional smaller electromagnetic coil or permanent magnet is centered on a spine on a side of the one or more three-dimensional magnetic nulls where magnetic fields intersect sensitive components.

6. The method of claim 2, wherein debris is routed along a spine that intersects collection optics and the debris is channeled through a hole in the collection optics.

7. The method of claim 2, wherein at least one of the plurality of electromagnetic coils and/or permanent magnets are superconducting.

8. The method of claim 2, wherein at least one permanent magnet is utilized to generate the one or more three-dimensional magnetic nulls.

9. The method of claim 2, further comprising varying current through the plurality of electromagnetic coils to control a structure and/or spatial location of the one or more three-dimensional magnetic nulls.

10. A laser plasma extreme ultraviolet (EUV) system, comprising:
a collection mirror;
a plurality of magnetic field generators configured to generate a three-dimensional magnetic null at a first location, the three-dimensional magnetic null defining a spine and a fan plane, the first location being spatially separated from the collection mirror, each magnetic field generator being an electromagnetic coil or a permanent magnet;
a droplet source configured to position a droplet of a material at the first location; and
an EUV light source configured to generate a beam of light that passes through a hole in the collection mirror and interacts with the droplet at the first location.

11. The laser plasma extreme ultraviolet (EUV) system of claim 10, wherein the plurality of magnetic field generators is a plurality of electromagnetic coils.

12. The laser plasma extreme ultraviolet (EUV) system of claim 11, wherein one or more of the plurality of electromagnetic coils are superconducting.

13. The laser plasma extreme ultraviolet (EUV) system of claim 10, wherein the plurality of magnetic field generators are disposed external to a light cone formed during operation of the laser plasma EUV system.

14. The laser plasma extreme ultraviolet (EUV) system of claim 10, wherein the plurality of magnetic field generators is configured to create a magnetic null with a planar fan plane.

15. The laser plasma extreme ultraviolet (EUV) system of claim 10, wherein the plurality of magnetic field generators is configured to create a magnetic null with a non-planar fan plane.

16. The laser plasma extreme ultraviolet (EUV) system of claim 10, wherein the plurality of magnetic field generators includes two magnetic field generators having a first average diameter, and an additional magnetic field generator having a second average diameter, the second average diameter being smaller than the first average diameter, the additional magnetic field generator being centered on a spine on a side of the three-dimensional magnetic null where magnetic fields intersect sensitive components.

17. The laser plasma extreme ultraviolet (EUV) system of claim 10, further comprising a power supply configured to vary current through the plurality of magnetic field generators to control a structure and/or spatial location of the three-dimensional magnetic null.

18. The laser plasma extreme ultraviolet (EUV) system according to claim 17, further comprising at least one processor configured to control the power supply.
